(19) United States
(12) Patent Application Publication
(10) Pub. No.: US 2008/0149949 A1
(43) Pub. Date: Jun. 26, 2008

(54) LEAD FRAME FOR TRANSPARENT AND MIRRORLESS LIGHT EMITTING DIODES

(75) Inventors: Shuji Nakamura, Santa Barbara, CA (US); Steven P. DenBaars, Goleta, CA (US)

Correspondence Address: GATES & COOPER LLP;HOWARD HUGHES CENTER, 6701 CENTER DRIVE WEST, SUITE 1050, LOS ANGELES, CA, 90045, US

(73) Assignee: THE REGENTS OF THE UNIVERSITY OF CALIFORNIA, Oakland, CA (US)

(21) Appl. No.: 11/954,163

(22) Filed: Dec. 11, 2007

Related U.S. Application Data
(60) Provisional application No. 60/869,454, filed on Dec. 11, 2006.

(51) Int. Cl. H01L 21/50; H01L 33/00

(52) U.S. Cl. 257/89; 438/26; 257/E33.066; 257/E21.499

(57) ABSTRACT

A lead frame for a transparent and mirrorless light emitting diode (LED). The LED is comprised of a plurality of III-nitride layers, including an active region that emits light, wherein all of the layers except for the active region are transparent for an emission wavelength of the light, such that the light is extracted effectively through all of the layers. A lead frame supports the III-nitride layers, wherein the III-nitride layers reside on a transparent plate in the lead frame, and the light emitted from the III-nitride layers is transmitted through the transparent plate. A metal mask may be formed on the transparent plate for electrically connecting the III-nitride layers to a lead frame.

### CROSS-REFERENCE TO RELATED APPLICATIONS

This application claims the benefit under 35 U.S.C. Section 119(e) of the following co-pending and commonly-assigned U.S. patent application:

U.S. Provisional Application Ser. No. 60/869,454, filed on Dec. 11, 2006, by Shuji Nakamura and Steven P. DenBaars, entitled “LEAD FRAME FOR TM-LED,” attorneys' docket number 30794.210-US-P1 (2007-281-1);

which application is incorporated by reference herein.

This application is related to the following co-pending and commonly-assigned applications:

U.S. Utility application Ser. No. 10/581,940, filed on Jun. 7, 2006, by Tetsuo Fujii, Yan Gao, Evelyn. L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-US-WO (2004-063), which application claims the benefit under 35 U.S.C Section 365(c) of PCT Application Serial No. US2003/03921, filed on Dec. 9, 2003, by Tetsuo Fujii, Yan Gao, Evelyn L. Hu, and Shuji Nakamura, entitled “HIGHLY EFFICIENT GALLIUM NITRIDE BASED LIGHT EMITTING DIODES VIA SURFACE ROUGHENING,” attorney's docket number 30794.108-WO-01 (2004-063);

U.S. Utility application Ser. No. 11/054,271, filed on Feb. 9, 2005, by Rajat Sharma, P. Morgan Pattison, John F. Kaeding, and Shuji Nakamura, entitled “SEMICONDUCTOR LIGHT EMITTING DEVICE,” attorney's docket number 30794.112-US-01 (2004-208);

U.S. Utility application Ser. No. 11/175,761, filed on Jul. 6, 2005, by Akihiko Murai, Lee McCarthy, Umesh K. Mishra and Steven P. DenBaars, entitled “METHOD FOR WAFER BONDING (Al, In, Ga)N and Zn(S, Se) FOR OPTOELECTRONICS APPLICATIONS,” attorney's docket number 30794.116-US-U1 (2004-455), which application claims the benefit under 35 U.S.C Section 119(e) of U.S. Provisional Application Ser. No. 60/585,673, filed Jul. 6, 2004, by Akihiko Murai, Lee McCarthy, Umesh K. Mishra and Steven P. DenBaars, entitled “METHOD FOR WAFER BONDING (Al, In, Ga)N and Zn(S, Se) FOR OPTOELECTRONICS APPLICATIONS,” attorney's docket number 30794.116-US-P1 (2004-455-1);

U.S. Utility application Ser. No. 11/697,457, filed Apr. 6, 2007, by, Benjamin A. Haskell, Melvin B. McLaurin, Steven P. DenBaars, James S. Speck, and Shuji Nakamura, entitled “GROWTH OF PLANAR REDUCED DISLOCATION DENSITY M-PLANE GALLIUM NITRIDE BY HYDRIDE VAPOR PHASE EPITAXY,” attorneys' docket number 30794.119-US-C1 (2004-636-3), which application is a continuation of U.S. Utility application Ser. No. 11/140,893, filed May 31, 2005, by, Benjamin A. Haskell, Melvin B. McLaurin, Steven P. DenBaars, James S. Speck, and Shuji Nakamura, entitled “GROWTH OF PLANAR REDUCED DISLOCATION DENSITY M-PLANE GALLIUM NITRIDE BY HYDRIDE VAPOR PHASE EPITAXY,” attorneys' docket number 30794.119-US-U1 (2004-636-2), now U.S. Pat. No. 7,208,393, issued Apr. 24, 2007, which application claims the benefit under 35 U.S.C. Section 119(e) of U.S. Provisional Application Ser. No. 60/576,685, filed Jun. 3, 2004, by Benjamin A. Haskell, Melvin B. McLaurin, Steven P. DenBaars, James S. Speck, and Shuji Nakamura, entitled “GROWTH OF PLANAR REDUCED DISLOCATION DENSITY M-PLANE GALLIUM NITRIDE BY HYDRIDE VAPOR PHASE EPITAXY,” attorneys' docket number 30794.119-US-P1 (2004-636-1);

U.S. Utility application Ser. No. 11/067,957, filed Feb. 28, 2005, by Claude C. A. Weisbuch, Aurelien J. F. David, James S. Speck and Steven P. DenBaars, entitled “HORIZONTAL EMITTING, VERTICAL EMITTING, BEAM SHAPED, DISTRIBUTED FEEDBACK (DFB) LASERS BY GROWTH OVER A PATTERNED SUBSTRATE,” attorneys' docket number 30794.121-US-01 (2005-144-1);

U.S. Utility application Ser. No. 11/923,414, filed Oct. 24, 2007, by Claude C. A. Weisbuch, Aurelien J. F. David, James S. Speck and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys' docket number 30794.122-US-C1 (2005-145-2), which application is a continuation of U.S. Pat. No. 7,291,864, issued Nov. 6, 2007, to Claude C. A. Weisbuch, Aurelien J. F. David, James S. Speck and Steven P. DenBaars, entitled “SINGLE OR MULTI-COLOR HIGH EFFICIENCY LIGHT EMITTING DIODE (LED) BY GROWTH OVER A PATTERNED SUBSTRATE,” attorneys' docket number 30794.122-US-01 (2005-145-1);

U.S. Utility application Ser. No. 11/067,956, filed Feb. 28, 2005, by Aurelien J. F. David, Claude C. A Weisbuch and Steven P. DenBaars, entitled “HIGH EFFICIENCY LIGHT EMITTING DIODE (LED) WITH OPTIMIZED PHOTONIC CRYSTAL EXTRACTOR,” attorneys' docket number 30794.126-US-01 (2005-198-1);

U.S. Utility application Ser. No. 11/621,482, filed Jan. 9, 2007, by Troy J. Baker, Benjamin A. Haskell, Paul T. Fini, Steven P. DenBaars, James S. Speck, and Shuji Nakamura, entitled “TECHNIQUE FOR THE GROWTH OF PLANAR SEMI-POLAR GALLIUM NITRIDE,” attorneys' docket number 30794.128-US-C1 (2005-471-3), which application is a continuation of U.S. Utility application Ser. No. 11/372,914, filed Mar. 10, 2006, by Troy J. Baker, Benjamin A. Haskell, Paul T. Fini, Steven P. DenBaars, James S. Speck, and Shuji Nakamura, entitled “TECHNIQUE FOR THE GROWTH OF PLANAR SEMI-POLAR GALLIUM NITRIDE,” attorneys' docket number 30794.128-US-U1 (2005-471-2), now U.S. Pat. No. 7,220,324, issued May 22, 2007, which application claims the benefit under 35 U.S.C. Section 119(e) of U.S. Provisional Application Ser. No. 60/660,283, filed Mar. 10, 2005, by Troy J. Baker, Benjamin A. Haskell, Paul T. Fini, Steven P. DenBaars, James S. Speck, and Shuji Nakamura, entitled “TECHNIQUE FOR THE GROWTH OF PLANAR SEMI-POLAR GALLIUM NITRIDE,” attorneys' docket number 30794.128-US-P1 (2005-471-1);

U.S. Utility application Ser. No. 11/403,624, filed Apr. 13, 2006, by James S. Speck, Troy J. Baker and Benjamin A. Haskell, entitled “WAFER SEPARATION TECHNIQUE FOR THE FABRICATION OF FREE-STANDING (AL, IN, GA)N WAFERS,” attorneys' docket number 30794.131-US-U1 (2005-482-2), which application claims the benefit under 35 U.S.C Section 119(e) of U.S. Provisional Application Ser. No. 60/670,810, filed Apr. 13, 2005, by James S. Speck, Troy J. Baker and Benjamin A. Haskell, entitled “WAFER SEPARATION TECHNIQUE FOR THE FABRICATION OF FREE-STANDING (AL, IN, GA)N WAFERS,” attorneys' docket number 30794.131-US-P1 (2005-482-1);

U.S. Utility application Ser. No. 11/403,288, filed Apr. 13, 2006, by James S. Speck, Benjamin A. Haskell, P. Morgan Pattison and Troy J. Baker, entitled “ETCHING TECHNIQUE FOR THE FABRICATION OF THIN (AL, IN, GA)N LAYERS,” attorneys' docket number 30794.132-US-U1 (2005-509-2), which application claims the benefit under 35 U.S.C Section 119(e) of U.S. Provisional Application Ser. No. 60/670,790, filed Apr. 13, 2005, by James S. Speck, Benjamin A. Haskell, P. Morgan Pattison and Troy J. Baker, entitled “ETCHING TECHNIQUE FOR THE FABRICATION OF THIN (AL, IN, GA)N LAYERS,” attorneys' docket number 30794.132-US-P1 (2005-509-1);

U.S. Utility application Ser. No. 11/454,691, filed on Jun. 16, 2006, by Akihiko Murai, Christina Ye Chen, Daniel B. Thompson, Lee S. McCarthy, Steven P. DenBaars, Shuji Nakamura, and Umesh K. Mishra, entitled “(Al,Ga,In)N AND ZnO DIRECT WAFER BONDING STRUCTURE FOR OPTOELECTRONIC APPLICATIONS AND ITS FABRICATION METHOD,” attorneys' docket number 30794.134-US-U1 (2005-536-4), which application claims the benefit under 35 U.S.C Section 119(e) of U.S. Provisional Application Ser. No. 60/691,710, filed on Jun. 17, 2005, by Akihiko Murai, Christina Ye Chen, Lee S. McCarthy, Steven P. DenBaars, Shuji Nakamura, and Umesh K. Mishra, entitled “(Al, Ga, In)N AND ZnO DIRECT WAFER BONDING STRUCTURE FOR OPTOELECTRONIC APPLICATIONS, AND ITS FABRICATION METHOD,” attorneys' docket number 30794.134-US-P1 (2005-536-1), U.S. Provisional Application Ser. No. 60/732,319, filed on Nov. 1, 2005, by Akihiko Murai, Christina Ye Chen, Daniel B. Thompson, Lee S. McCarthy, Steven P. DenBaars, Shuji Nakamura, and Umesh K. Mishra, entitled “(Al, Ga, In)N AND ZnO DIRECT WAFER BONDED STRUCTURE FOR OPTOELECTRONIC APPLICATIONS, AND ITS FABRICATION METHOD,” attorneys' docket number 30794.134-US-P2 (2005-536-2), and U.S. Provisional Application Ser. No. 60/764,881, filed on Feb. 3, 2006, by Akihiko Murai, Christina Ye Chen, Daniel B. Thompson, Lee S. McCarthy, Steven P. DenBaars, Shuji Nakamura, and Umesh K. Mishra, entitled “(Al,Ga,In)N AND ZnO DIRECT WAFER BONDED STRUCTURE FOR OPTOELECTRONIC APPLICATIONS AND ITS FABRICATION METHOD,” attorneys' docket number 30794.134-US-P3 (2005-536-3);

U.S. Utility application Ser. No. 11/444,084, filed May 31, 2006, by Bilge M, Imer, James S. Speck, and Steven P. DenBaars, entitled “DEFECT REDUCTION OF NON-POLAR GALLIUM NITRIDE WITH SINGLE-STEP SIDEWALL LATERAL EPITAXIAL OVERGROWTH,” attorneys' docket number 30794.135-US-U1 (2005-565-2), which claims the benefit under 35 U.S.C. 119(e) of U.S. Provisional Application Ser. No. 60/685,952, filed on May 31, 2005, by Bilge M, Imer, James S. Speck, and Steven P. DenBaars, entitled “DEFECT REDUCTION OF NON-POLAR GALLIUM NITRIDE WITH SINGLE-STEP SIDEWALL LATERAL EPITAXIAL OVERGROWTH,” attorneys' docket number 30794.135-US-P1 (2005-565-1);

U.S. Utility application Ser. No. 11/870,115, filed Oct. 10, 2007, by Bilge M, Imer, James S. Speck, Steven P. DenBaars and Shuji Nakamura, entitled “GROWTH OF PLANAR NON-POLAR M-PLANE III-NITRIDE USING METALORGANIC CHEMICAL VAPOR DEPOSITION (MOCVD),” attorneys' docket number 30794.136-US-C1 (2005-566-3), which application is a continuation of U.S. Utility application Ser. No. 11/444,946, filed May 31, 2006, by Bilge M, Imer, James S. Speck, and Steven P. DenBaars, entitled “GROWTH OF PLANAR NON-POLAR {1-100} M-PLANE GALLIUM NITRIDE WITH METALORGANIC CHEMICAL VAPOR DEPOSITION (MOCVD),” attorneys' docket number 30794.136-US-U1 (2005-566-2), which claims the benefit under 35 U.S.C. 119(e) of U.S. Provisional Application Ser. No. 60/685,908, filed on May 31, 2005, by Bilge M, Imer, James S. Speck, and Steven P. DenBaars, entitled “GROWTH OF PLANAR NON-POLAR {1-100} M-PLANE GALLIUM NITRIDE WITH METALORGANIC CHEMICAL VAPOR DEPOSITION (MOCVD),” attorneys' docket number 30794.136-US-P1 (2005-566-1);

U.S. Utility application Ser. No. 11/444,946, filed Jun. 1, 2006, by Robert M. Farrell, Troy J. Baker, Arpan Chakraborty, Benjamin A. Haskell, P. Morgan Pattison, Rajat Sharma, Umesh K. Mishra, Steven P. DenBaars, James S. Speck, and Shuji Nakamura, entitled “TECHNIQUE FOR THE GROWTH AND FABRICATION OF SEMIPOLAR (Ga, Al, In, B)N THIN FILMS, HETEROSTRUCTURES, AND DEVICES,” attorneys' docket number 30794.140-US-U1 (2005-668-2), which claims the benefit under 35 U.S.C. 119(e) of U.S. Provisional Application Ser. No. 60/686,244, filed on Jun. 1, 2005, by Robert M. Farrell, Troy J. Baker, Arpan Chakraborty, Benjamin A. Haskell, P. Morgan Pattison, Rajat Sharma, Umesh K. Mishra, Steven P. DenBaars, James S. Speck, and Shuji Nakamura, entitled “TECHNIQUE FOR THE GROWTH AND FABRICATION OF SEMIPOLAR (Ga, Al, In, B)N THIN FILMS, HETEROSTRUCTURES, AND DEVICES,” attorneys' docket number 30794.140-US-P1 (2005-668-1);

U.S. Utility application Ser. No. 11/251,365 filed Oct. 14, 2005, by Frederic S. Diana, Aurelien J. F. David, Pierre M. Petroff, and Claude C. A. Weisbuch, entitled “PHOTONIC STRUCTURES FOR EFFICIENT LIGHT EXTRACTION AND CONVERSION IN MULTI-COLOR LIGHT EMITTING DEVICES,” attorneys' docket number 30794.142-US-01 (2005-534-1);

U.S. Utility application Ser. No. 11/633,148, filed Dec. 4, 2006, Claude C. A. Weisbuch and Shuji Nakamura, entitled “IMPROVED HORIZONTAL EMITTING, VERTICAL EMITTING, BEAM SHAPED, DISTRIBUTED FEEDBACK (DFB) LASERS FABRICATED BY GROWTH OVER A PATTERNED SUBSTRATE WITH MULTIPLE OVERGROWTH,” attorneys' docket number 30794.143-US-U1 (2005-721-2), which application claims the benefit under 35 U.S.C Section 119(e) of U.S. Provisional Application Ser. No. 60/741,935, filed Dec. 2, 2005, Claude C. A. Weisbuch and Shuji Nakamura, entitled “IMPROVED HORIZONTAL EMITTING, VERTICAL EMITTING, BEAM SHAPED, DFB LASERS FABRICATED BY GROWTH OVER PATTERNED SUBSTRATE WITH MULTIPLE OVERGROWTH,” attorneys' docket number 30794.143-US-P1 (2005-721-1);

U.S. Utility application Ser. No. 11/517,797, filed Sep. 8, 2006, by Michael Iza, Troy J. Baker, Benjamin A. Haskell, Steven P. DenBaars, and Shuji Nakamura, entitled “METHOD FOR ENHANCING GROWTH OF SEMIPOLAR (Al, In, Ga, B)N VIA METALORGANIC CHEMICAL VAPOR DEPOSITION,” attorneys' docket number 30794.144-US-U1 (2005-722-2), which claims the benefit under 35 U.S.C. 119(e) of U.S. Provisional Application Ser. No. 60/715,491, filed on Sep. 9, 2005, by Michael Iza, Troy J. Baker, Benjamin A. Haskell, Steven P. DenBaars, and Shuji Nakamura, entitled “METHOD FOR ENHANCING GROWTH OF SEMIPOLAR (Al, In, Ga, B)N VIA METALORGANIC CHEMICAL VAPOR DEPOSITION,” attorneys' docket number 30794.144-US-U1 (2005-722-1);

U.S. Utility application Ser. No. 11/593,268, filed on Nov. 6, 2006, by Steven P. DenBaars, Shuji Nakamura, Hisashi Masui, Natalie N. Fellows, and Akihiko Murai, entitled “HIGH LIGHT EXTRACTION EFFICIENCY LIGHT EMITTING DIODE (LED),” attorneys' docket number 30794.161-US-U1 (2006-271-2), which application claims the benefit under 35 U.S.C Section 119(e) of U.S. Provisional Application Ser. No. 60/734,040, filed on Nov. 4, 2005, by Steven P. DenBaars, Shuji Nakamura, Hisashi Masui, Natalie N. Fellows, and Akihiko Murai, entitled “HIGH LIGHT EXTRACTION EFFICIENCY LIGHT EMITTING DIODE (LED),” attorneys' docket number 30794.161-US-P1 (2006-271-1);

U.S. Utility application Ser. No. 11/608,439, filed on Dec. 8, 2006, by Steven P. DenBaars, Shuji Nakamura and James S. Speck, entitled “HIGH EFFICIENCY LIGHT EMITTING DIODE (LED),” attorneys' docket number 30794.164-US-U1 (2006-318-3), which application claims the benefit under 35 U.S.C Section 119(e) of U.S. Provisional Application Ser. No. 60/748,480, filed on Dec. 8, 2005, by Steven P. DenBaars, Shuji Nakamura and James S. Speck, entitled “HIGH EFFICIENCY LIGHT EMITTING DIODE (LED),” attorneys' docket number 30794.164-US-P1 (2006-318-1), and U.S. Provisional Application Ser. No. 60/764,975, filed on Feb. 3, 2006, by Steven P. DenBaars, Shuji Nakamura and James S. Speck, entitled “HIGH EFFICIENCY LIGHT EMITTING DIODE (LED),” attorneys' docket number 30794.164-US-P2 (2006-318-2);

U.S. Utility application Ser. No. 11/676,999, filed on Feb. 20, 2007, by Hong Zhong, John F. Kaeding, Rajat Sharma, James S. Speck, Steven P. DenBaars and Shuji Nakamura, entitled “METHOD FOR GROWTH OF SEMIPOLAR (Al,In,Ga,B)N OPTOELECTRONIC DEVICES,” attorneys' docket number 30794.173-US-U1 (2006-422-2), which application claims the benefit under 35 U.S.C Section 119(e) of U.S. Provisional Application Ser. No. 60/774,467, filed on Feb. 17, 2006, by Hong Zhong, John F. Kaeding, Rajat Sharma, James S. Speck, Steven P. DenBaars and Shuji Nakamura, entitled “METHOD FOR GROWTH OF SEMIPOLAR (Al,In,Ga,B)N OPTOELECTRONIC DEVICES,” attorneys' docket number 30794.173-US-P1 (2006-422-1);

U.S. Utility patent application Ser. No. 11/840,057, filed on Aug. 16, 2007, by Michael Iza, Hitoshi Sato, Steven P. DenBaars, and Shuji Nakamura, entitled “METHOD FOR DEPOSITION OF MAGNESIUM DOPED (Al, In, Ga, B)N LAYERS,” attorney's docket number 30794.187-US-U1 (2006-678-2), which claims the benefit under 35 U.S.C. 119(e) of U.S. Provisional Patent Application Ser. No. 60/822,600, filed on Aug. 16, 2006, by Michael Iza, Hitoshi Sato, Steven P. DenBaars, and Shuji Nakamura, entitled “METHOD FOR DEPOSITION OF MAGNESIUM DOPED (Al, In, Ga, B)N LAYERS,” attorney's docket number 30794.187-US-P1 (2006-678-1);

U.S. Utility patent application Ser. No. 11/940,848, filed on Nov. 15, 2007, by Aurelien J. F. David, Claude C. A. Weisbuch and Steven P. DenBaars entitled “HIGH LIGHT EXTRACTION EFFICIENCY LIGHT EMITTING DIODE (LED) THROUGH MULTIPLE EXTRACTORS,” attorney's docket number 30794.191-US-U1 (2007-047-3), which application claims the benefit under 35 U.S.C Section 119(e) of U.S. Provisional Patent Application Ser. No. 60/866,014, filed on Nov. 15, 2006, by Aurelien J. F. David, Claude C. A. Weisbuch and Steven P. DenBaars entitled “HIGH LIGHT EXTRACTION EFFICIENCY LIGHT EMITTING DIODE (LED) THROUGH MULTIPLE EXTRACTORS,” attorney's docket number 30794.191-US-P1 (2007-047-1), and U.S. Provisional Patent Application Ser. No. 60/883,977, filed on Jan. 8, 2007, by Aurelien J. F. David, Claude C. A. Weisbuch and Steven P. DenBaars entitled “HIGH LIGHT EXTRACTION EFFICIENCY LIGHT EMITTING DIODE (LED) THROUGH MULTIPLE EXTRACTORS,” attorney's docket number 30794.191-US-P2 (2007-047-2);

U.S. Utility patent application Ser. No. 11/940,853, filed on Nov. 15, 2007, by Claude C. A. Weisbuch, James S. Speck and Steven P. DenBaars entitled “HIGH EFFICIENCY WHITE, SINGLE OR MULTI-COLOUR LIGHT EMITTING DIODES (LEDS) BY INDEX MATCHING STRUCTURES,” attorney's docket number 30794.196-US-U1 (2007-114-2), which application claims the benefit under 35 U.S.C Section 119(e) of U.S. Provisional Patent Application Ser. No. 60/866,026, filed on Nov. 15, 2006, by Claude C. A. Weisbuch, James S. Speck and Steven P. DenBaars entitled “HIGH EFFICIENCY WHITE, SINGLE OR MULTI-COLOUR LED BY INDEX MATCHING STRUCTURES,” attorney's docket number 30794.196-US-P1 (2007-114-1);

U.S. Utility patent application Ser. No. 11/940,866, filed on Nov. 15, 2007, by Aurelien J. F. David, Claude C. A. Weisbuch, Steven P. DenBaars and Stacia Keller, entitled “HIGH LIGHT EXTRACTION EFFICIENCY LIGHT EMITTING DIODE (LED) WITH EMITTERS WITHIN STRUCTURED MATERIALS,” attorney's docket number 30794.197-US-U1 (2007-113-2), which application claims the benefit under 35 U.S.C Section 119(e) of U.S. Provisional Patent Application Ser. No. 60/866,015, filed on Nov. 15, 2006, by Aurelien J. F. David, Claude C. A. Weisbuch, Steven P. DenBaars and Stacia Keller, entitled “HIGH LIGHT EXTRACTION EFFICIENCY LED WITH EMITTERS WITHIN STRUCTURED MATERIALS,” attorney's docket number 30794.197-US-P1 (2007-113-1);

U.S. Utility patent application Ser. No. 11/940,876, filed on Nov. 15, 2007, by Evelyn L. Hu, Shuji Nakamura, Yong Seok Choi, Rajat Sharma and Chiou-Fu Wang, entitled “ION BEAM TREATMENT FOR THE STRUCTURAL INTEGRITY OF AIR-GAP III-NITRIDE DEVICES PRODUCED BY PHOTOELECTROCHEMICAL (PEC) ETCHING,” attorney's docket number 30794.201-US-U1 (2007-161-2), which application claims the benefit under 35 U.S.C Section 119(e) of U.S. Provisional Patent Application Ser. No. 60/866,027, filed on Nov. 15, 2006, by Evelyn L. Hu, Shuji Nakamura, Yong Seok Choi, Rajat Sharma and Chiou-Fu Wang, entitled “ION BEAM TREATMENT FOR THE STRUCTURAL INTEGRITY OF AIR-GAP III-NITRIDE DEVICES PRODUCED BY PHOTOELECTROCHEMICAL (PEC) ETCHING,” attorney's docket number 30794.201-US-P1 (2007-161-1);

U.S. Utility patent application Ser. No. 11/940,885, filed on Nov. 15, 2007, by Natalie N. Fellows, Steven P. DenBaars and Shuji Nakamura, entitled “TEXTURED PHOSPHOR CONVERSION LAYER LIGHT EMITTING DIODE,” attorney's docket number 30794.203-US-U1 (2007-270-2), which application claims the benefit under 35 U.S.C Section 119(e) of U.S. Provisional Patent Application Ser. No. 60/866,024, filed on Nov. 15, 2006, by Natalie N. Fellows, Steven P. DenBaars and Shuji Nakamura, entitled “TEXTURED PHOSPHOR CONVERSION LAYER LIGHT EMITTING DIODE,” attorney's docket number 30794.203-US-P1 (2007-270-1);

U.S. Utility patent application Ser. No. 11/940,872, filed on Nov. 15, 2007, by Steven P. DenBaars, Shuji Nakamura and Hisashi Masui, entitled “HIGH LIGHT EXTRACTION EFFICIENCY SPHERE LED,” attorney's docket number 30794.204-US-U1 (2007-271-2), which application claims the benefit under 35 U.S.C Section 119(e) of U.S. Provisional Patent Application Ser. No. 60/866,025, filed on Nov. 15, 2006, by Steven P. DenBaars, Shuji Nakamura and Hisashi Masui, entitled “HIGH LIGHT EXTRACTION EFFICIENCY SPHERE LED,” attorney's docket number 30794.204-US-P1 (2007-271-1);

U.S. Utility patent application Ser. No. 11/940,883, filed on Nov. 15, 2007, by Shuji Nakamura and Steven P. DenBaars, entitled “STANDING TRANSPARENT MIRRORLESS LIGHT EMITTING DIODE,” attorney's docket number 30794.205-US-U1 (2007-272-2), which application claims the benefit under 35 U.S.C Section 119(e) of U.S. Provisional Patent Application Ser. No. 60/866,017, filed on Nov. 15, 2006, by Shuji Nakamura and Steven P. DenBaars, entitled “STANDING TRANSPARENT MIRROR-LESS (STML) LIGHT EMITTING DIODE,” attorney's docket number 30794.205-US-P1 (2007-272-1); and

U.S. Utility patent application Ser. No. 11/940,898, filed on Nov. 15, 2007, by Steven P. DenBaars, Shuji Nakamura and James S. Speck, entitled “TRANSPARENT MIRRORLESS LIGHT EMITTING DIODE,” attorney's docket number 30794.206-US-U1 (2007-273-2), which application claims the benefit under 35 U.S.C Section 119(e) of U.S. Provisional Patent Application Ser. No. 60/866,023, filed on Nov. 15, 2006, by Steven P. DenBaars, Shuji Nakamura and James S. Speck, entitled “TRANSPARENT MIRROR-LESS (TML) LIGHT EMITTING DIODE,” attorney's docket number 30794.206-US-P1 (2007-273-1);

U.S. Utility patent application Ser. No. ______, filed on Dec. 11, 2007, by Shuji Nakamura, Steven P. DenBaars, and Hirokuni Asamizu, entitled “TRANSPARENT LIGHT EMITTING DIODES,” attorney's docket number 30794.211-US-U1 (2007-282-2), which claims the benefit under 35 U.S.C. 119(e) of U.S. Provisional Patent Application Ser. No. 60/869,447, filed on Dec. 11, 2006, by Shuji Nakamura, Steven P. DenBaars, and Hirokuni Asamizu, entitled “TRANSPARENT LEDS,” attorney's docket number 30794.211-US-P1 (2007-282-1);

U.S. Utility patent application Ser. No. ______, filed on Dec. 11, 2007, by Mathew C. Schmidt, Kwang Choong Kim, Hitoshi Sato, Steven P. DenBaars, James S. Speck, and Shuji Nakamura, entitled “METALORGANIC CHEMICAL VAPOR DEPOSITION (MOCVD) GROWTH OF HIGH PERFORMANCE NON-POLAR III-NITRIDE OPTICAL DEVICES,” attorney's docket number 30794.212-US-U1 (2007-316-2), which claims the benefit under 35 U.S.C. 119(e) of U.S. Provisional Patent Application Ser. No. 60/869,535, filed on Dec. 11, 2006, by Mathew C. Schmidt, Kwang Choong Kim, Hitoshi Sato, Steven P. DenBaars, James S. Speck, and Shuji Nakamura, entitled “MOCVD GROWTH OF HIGH PERFORMANCE M-PLANE GAN OPTICAL DEVICES,” attorney's docket number 30794.212-US-P1 (2007-316-1);

U.S. Utility patent application Ser. No. ______, filed on Dec. 11, 2007, by Steven P. DenBaars, Mathew C. Schmidt, Kwang Choong Kim, James S. Speck, and Shuji Nakamura, entitled “NON-POLAR AND SEMI-POLAR EMITTING DEVICES,” attorney's docket number 30794.213-US-U1 (2007-317-2), which claims the benefit under 35 U.S.C. 119(e) of U.S. Provisional Patent Application Ser. No. 60/869,540, filed on Dec. 11, 2006, by Steven P. DenBaars, Mathew C. Schmidt, Kwang Choong Kim, James S. Speck, and Shuji Nakamura, entitled “NON-POLAR (M-PLANE) AND SEMI-POLAR EMITTING DEVICES,” attorney's docket number 30794.213-US-P1 (2007-317-1);

U.S. Utility patent application Ser. No. ______, filed on Dec. 11, 2007, by Kwang Choong Kim, Mathew C. Schmidt, Feng Wu, Asako Hirai, Melvin B. McLaurin, Steven P. DenBaars, Shuji Nakamura, and James S. Speck, entitled “CRYSTAL GROWTH OF M-PLANE AND SEMIPOLAR PLANES OF (AL, IN, GA, B)N ON VARIOUS SUBSTRATES,” attorney's docket number 30794.214-US-U1 (2007-334-2), which claims the benefit under 35 U.S.C. 119(e) of U.S. Provisional Patent Application Ser. No. 60/869,701, filed on Dec. 12, 2006, by Kwang Choong Kim, Mathew C. Schmidt, Feng Wu, Asako Hirai, Melvin B. McLaurin, Steven P. DenBaars, Shuji Nakamura, and James S. Speck, entitled “CRYSTAL GROWTH OF M-PLANE AND SEMIPOLAR PLANES OF (AL, IN, GA, B)N ON VARIOUS SUBSTRATES,” attorney's docket number 30794.214-US-P1 (2007-334-1);

all of which applications are incorporated by reference herein.

### BACKGROUND OF THE INVENTION

1. Field of the Invention

The present invention is related to light extraction from light emitting diodes (LEDs).

2. Description of the Related Art

(Note: This application references a number of different publications as indicated throughout the specification. In addition, a list of a number of different publications can be found below in the section entitled “References.” Each of these publications is incorporated by reference herein).

In order to increase the light output power from the front side of an LED, the emitted light is reflected by a mirror placed on the backside of the substrate or is reflected by a mirror coating on the lead frame, even if there are no mirrors on the backside of the substrate, if the bonding material is transparent on the emission wavelength. However, this reflected light is re-absorbed by the emitting layer (active layer), because the photon energy is almost same as the band-gap energy of the light emitting species, such as AlInGaN multiple quantum wells (MQWs). The efficiency or output power of the LEDs is decreased due to this re-absorption of the light by the emitting layer. See, for example, FIGS. 1, 2 and 3, which are described in more detail below. See also Jpn. J. Appl. Phys., 34, L797-99 (1995) and Jpn. J. Appl. Phys., 43, L180-82 (2004).

What is needed in the art are LED structures that more effectively extract light. The present invention satisfies that need.

### SUMMARY OF THE INVENTION

The present invention describes a lead frame for a transparent and mirrorless light emitting diode. Generally, the present invention describes a light emitting device comprised of a plurality of III-nitride layers, including an active region that emits light, wherein all of the layers except for the active region are transparent for an emission wavelength of the light, such that the light is extracted effectively through all of the layers; and a lead frame for supporting the III-nitride layers, wherein the III-nitride layers reside on a transparent plate in the lead frame, and the light emitted from the III-nitride layers is transmitted through the transparent plate. A metal mask may be formed on the transparent plate for electrically connecting the III-nitride layers to the lead frame. The surface of one or more of the III-nitride layers may be roughened, textured, patterned or shaped to enhance light extraction.

In one embodiment, the III-nitride layers reside on a transparent substrate or sub-mount. Moreover, the device may include one or more transparent conducting layers that are positioned to electrically connect the III-nitride layers, and one or more current spreading layers that are deposited on the III-nitride layers, wherein the transparent conducting layers are deposited on the current spreading layers. Mirrors or mirrored surfaces are eliminated from the device to minimize internal reflections in order to minimize re-absorption of the light by the active region.

In another embodiment, the III-nitride layers are embedded in or combined with a shaped optical element, and the light is extracted from more than one surface of the III-nitride layers before entering the shaped optical element and subsequently being extracted. Specifically, at least a portion of the light entering the shaped optical element lies within a critical angle and is extracted. Moreover, one or more surfaces of the shaped optical element may be roughened, textured, patterned or shaped to enhance light extraction. Further, the shaped optical element may include a phosphor layer. The shaped optical element may be an inverted cone shape, wherein the III-nitride layers are positioned within the inverted cone shape such that the light is reflected by sidewalls of the inverted cone shape.

In yet another embodiment, an insulating layer covering the III-nitride layers is partially removed, and a conductive layer is deposited within a hole or depression in the surface of the insulating layer to make electrical contact with the III-nitride layers.

In still another embodiment, the active region includes multiple emitting layers emitting the light at different wavelengths. In addition, a light mixing layer mixes the light at different wavelengths emitted by the multiple emitting layers of the active region.

### BRIEF DESCRIPTION OF THE DRAWINGS

Referring now to the drawings in which like reference numbers represent corresponding parts throughout:

FIGS. 1, 2 and 3 are schematic illustrations of conventional LEDs.

FIGS. 4A and 4B are schematic and plan view illustrations, respectively, of an improved LED structure according to the preferred embodiment of the present invention.

FIGS. 5A and 5B are schematic and plan view illustrations, respectively, of an improved LED structure according to the preferred embodiment of the present invention.

FIGS. 6A and 6B are schematic and plan view illustrations, respectively, of an improved LED structure according to the preferred embodiment of the present invention.

FIGS. 7A and 7B are schematic and plan view illustrations, respectively, of an improved LED structure according to the preferred embodiment of the present invention.

FIGS. 8A and 8B are schematic and plan view illustrations, respectively, of an improved LED structure according to the preferred embodiment of the present invention.

FIGS. 9A and 9B are schematic and plan view illustrations, respectively, of an improved LED structure according to the preferred embodiment of the present invention.

FIG. 10 is a schematic illustration of an improved LED structure according to the preferred embodiment of the present invention.

FIG. 11 is a schematic illustration of an improved LED structure according to the preferred embodiment of the present invention.

FIG. 12 is a schematic illustration of an improved LED structure according to the preferred embodiment of the present invention.

FIG. 13 is a schematic illustration of an improved LED structure according to the preferred embodiment of the present invention.

### DETAILED DESCRIPTION OF THE INVENTION

In the following description of the preferred embodiment, reference is made to the accompanying drawings which form a part hereof, and in which is shown by way of illustration a specific embodiment in which the invention may be practiced. It is to be understood that other embodiments may be utilized and structural changes may be made without departing from the scope of the present invention.

Overview

In the following description of the figures, the details of the LED structures are not shown. Only the emitting layer (usually AlInGaN MQW), p-type GaN layer, n-type GaN layer, and substrate are shown. Of course, there may be other layers in the LED structure. In this invention, the most important aspects are the surfaces of the LED structure, because the light extraction efficiency is determined mainly by the surface layer or condition of the epitaxial wafers. Consequently, only some aspects (the surface layers) of the LED are shown in all of the figures.

Conventional LED Structures

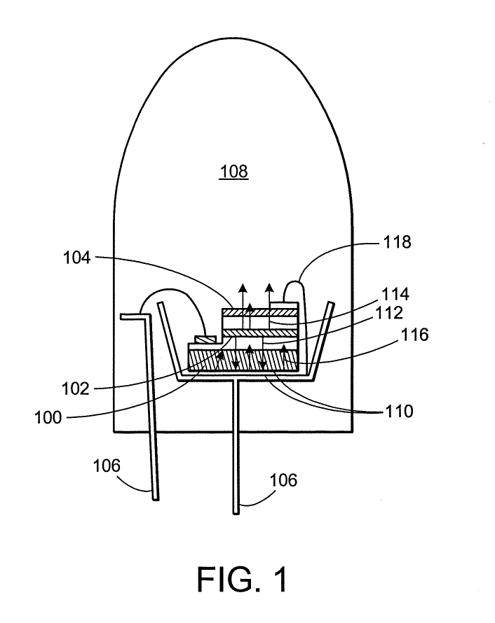

FIGS. 1, 2 and 3 are schematic illustrations of LED configurations.

In order to increase the light output power from the front side of the LED, the emitting light is reflected by the mirror on the backside of the substrate or the mirror coating on the lead frame, even if there is no mirrors on the backside of the substrate, if the bonding material is transparent on the emission wavelength. This reflected light is re-absorbed by the emitting layer (active layer), because the photon energy is almost same as the band-gap energy of the quantum well of AlInGaN multiple quantum well (MQW). The efficiency or output power of the LEDs is decreased due to the re-absorption by the emitting layer.

In FIG. 1, the LED structure includes a sapphire substrate 100, emitting layer 102 (active layer), and semi-transparent or transparent electrodes 104, such as ITO or ZnO. The LED is die-bonded on a lead frame 106 with a clear epoxy molding 108 without any mirror on the back side of the sapphire substrate 100. In this case, the coating material on the lead frame 106, or the surface of the lead frame 106, becomes a mirror 110. If there is a mirror 110 on the back side of the substrate 100, the LED is die-bonded using an Ag paste. The active layer 102 emits light 112 towards the substrate 100 and emits light 114 towards the electrodes 104. The emitting light 112 is reflected by the mirror 110 towards the electrode 104, becoming reflected light 116 which is transmitted by the electrode 104 to escape the LED. Finally, wire bonding 118 is used to connect the LED to the lead frame 106.

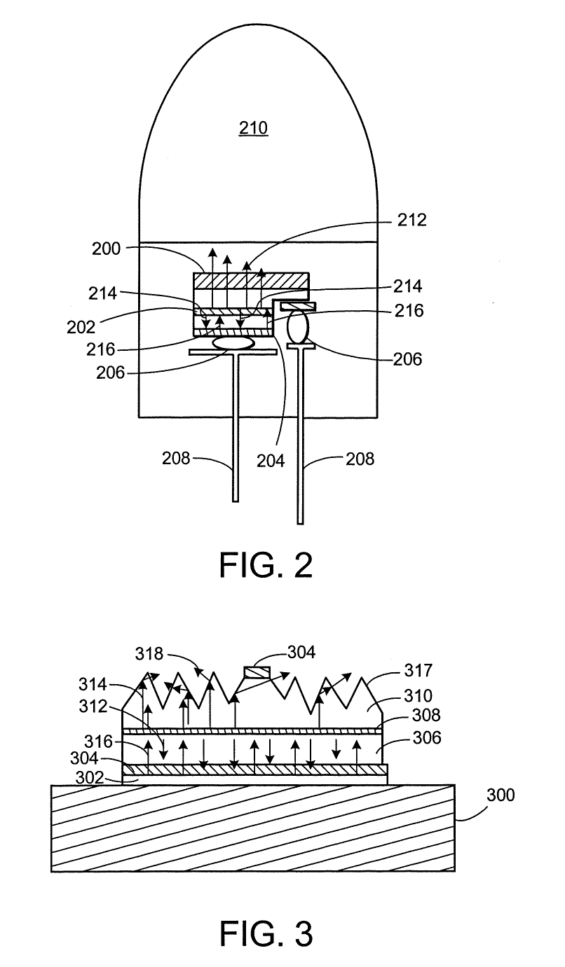

In FIG. 2, the LED structure is similar to that shown in FIG. 1, except that it is a flip-chip LED. The LED includes a sapphire substrate 200, emitting layer 202 (active layer), and a highly reflective mirror 204. The LED is die-bonded 206 onto a lead frame 208 and embedded in a clear epoxy molding 210. The active layer 202 emits light 212 towards the substrate 200 and emits light 214 towards the highly reflective mirror 204. The emitting light 214 is reflected by the mirror 204 towards the substrate 200, becoming reflected light 216 which is transmitted by the substrate 200 to escape the LED.

In FIG. 3, the LED structure includes a conducting sub-mount 300, high reflectivity mirror 302 (with Ag>94% reflectivity (R)), transparent ITO layer 304, p-type GaN layer 306, emitting or active layer 308, and n-type GaN layer 310. The LED is shown without the epoxy molding, although similar molding may be used. The emitting layer 308 emits light 312 towards the mirror 302 and the emitting layer 308 emits light 314 towards the n-GaN layer 310. The emitted light 312 is reflected by the mirror 302, where the reflected light 316 is re-absorbed by the emitting layer 308. The efficiency of the LED is decreased due to this re-absorption. In addition, the n-type GaN layer may be roughened 317 to enhance extraction 318 of the emitted light 314.

Improved LED Structures

The present invention describes a lead frame for a transparent and mirrorless LED. Generally, the present invention describes a light emitting device comprised of a plurality of III-nitride layers, including an active region that emits light, wherein all of the layers except for the active region are transparent for an emission wavelength of the light, such that the light is extracted effectively through all of the layers; and a lead frame for supporting the III-nitride layers, wherein the III-nitride layers reside on a transparent plate in the lead frame, and the light emitted from the III-nitride layers is transmitted through the transparent plate. A metal mask may be formed on the transparent plate for electrically connecting the III-nitride layers to a lead frame. The surface of one or more of the III-nitride layers may be roughened, textured, patterned or shaped to enhance light extraction.

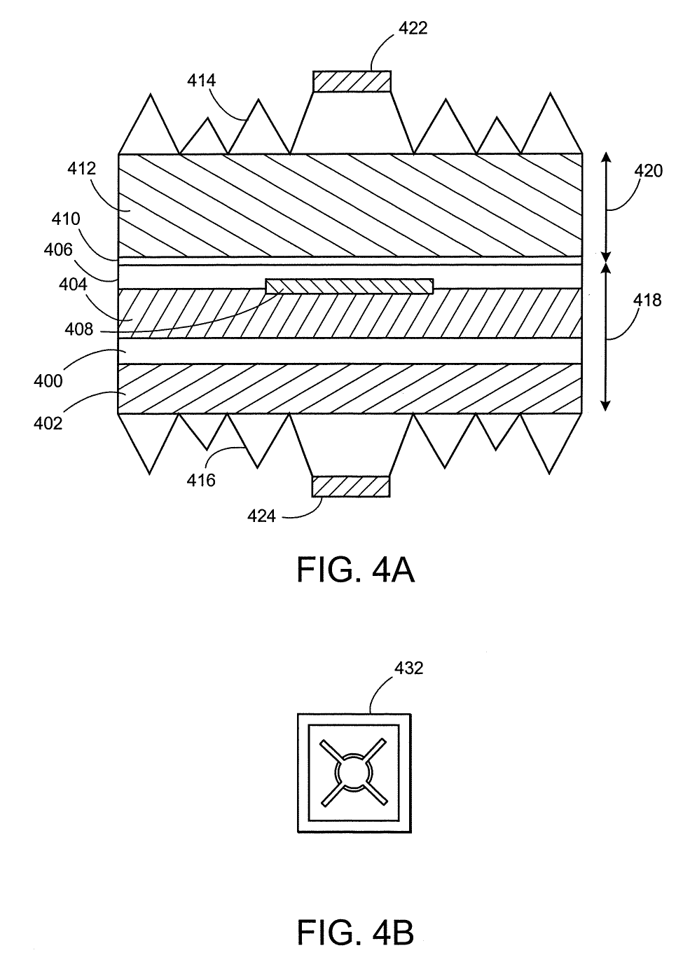

FIG. 4A is a schematic illustrating a specific improved LED structure according the preferred embodiment of the present invention, wherein the improved LED structure comprises an InGaN multi quantum well (MQW) layer as an emitting layer 400, an n-type GaN layer 402, a p-type GaN layer 404, an ITO or ZnO transparent conducting layer 406, a transparent insulating layer 408, and a transparent conductive glue 410 for bonding the ITO or ZnO transparent conducting layer 406 to a transparent conductive substrate 412, wherein the transparent conductive substrate 412 has a surface 414 that is roughened, textured, patterned or shaped, and the n-type GaN layer 404 has a surface 416 that is roughened, textured, patterned or shaped. The layers 400, 402 and 404 have a combined thickness 418 of approximately 4 microns, and the substrate 412 and glue 410 have a combined thickness 420 of approximately 400 microns. Ohmic electrode/bonding pads 422, 424 are also placed on the LED. FIG. 4B is a plan view of the LED of FIG. 4A.

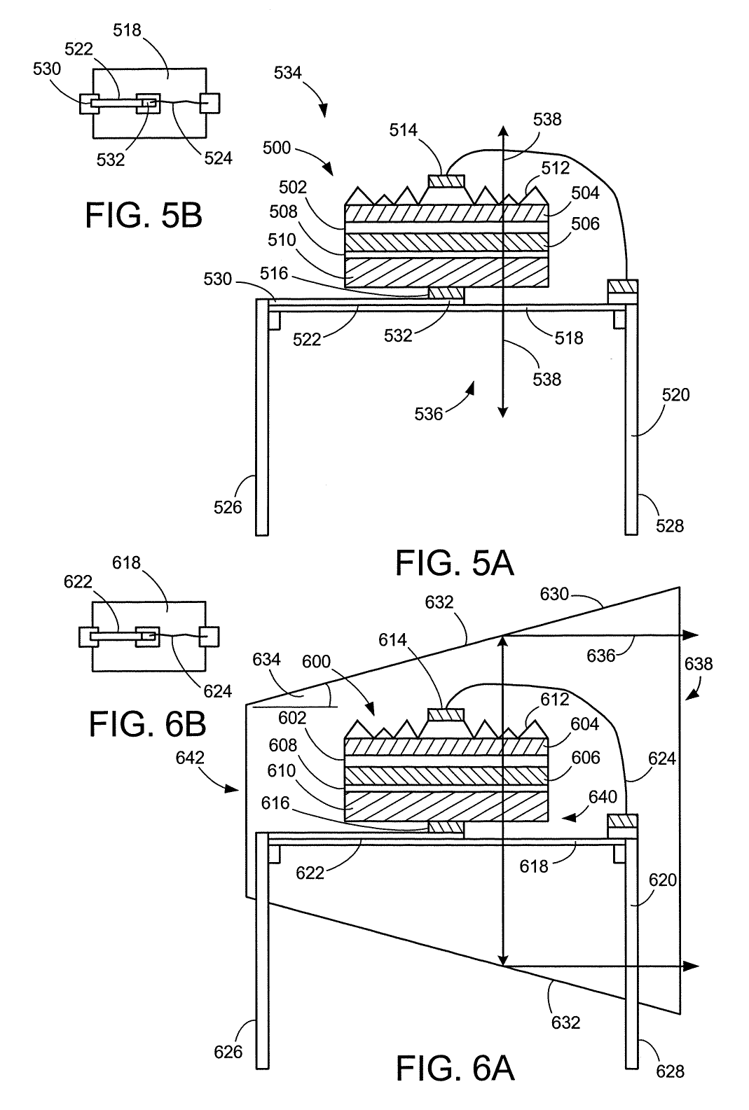

FIG. 5A is a schematic illustrating a specific improved LED structure according the preferred embodiment of the present invention, wherein the improved LED structure 500 comprises an emitting layer 502, an n-type GaN layer 504, a p-type GaN layer 506, an ITO or ZnO layer 508, a transparent sub-mount 510, a surface 512 of the n-type GaN layer 504 that is roughened, textured, patterned or shaped, an n-type GaN bonding pad 514 contacting the n-type GaN layer 504 and a p-type GaN bonding pad 516 contacting the p-type GaN layer 506. The LED 500 resides on a transparent plate 518, which resides on a metal lead frame 520, wherein a metal mask 522 is formed on the transparent plate 518. A wire bond 524 is made from the bonding pad 514 to the metal lead frame 520. The lead frame 520 has an anode 526 and a cathode 528. FIG. 5B is a plan view of the LED of FIG. 5A.

In both FIG. 4A and FIG. 5A, the LED structure is grown on a sapphire substrate, which is removed using a laser de-bonding technique. Thereafter, the ITO layers 406, 508 are deposited on the p-type GaN layers 404, 506.

In the embodiment of FIG. 4A, before deposition of the ITO layer 406, an insulating layer 408, such as SiO₂ or SiN, may be deposited as a current spreading layer. Without the current spreading layer 408, the emission intensity of the LED becomes small due to non-uniform current flows. The transparent conductive substrate 412, which may be ZnO, Ga₂O₃ or another material that is transparent at the desired wavelengths, is wafer bonded or glued to the ITO layer 406 using the transparent conductive glue 410. Then, an n-GaN ohmic electrode/bonding pad 422 and an p-GaN ohmic electrode/bonding pad 424 are formed on both sides of the LED structure. Finally, the nitrogen-face (N-face) of the n-type GaN layer 402 is roughened, textured, patterned or shaped 416 to enhance light extraction, for example, using a wet etching, such as KOH or HCL, to form a cone-shaped surface 416.

In the embodiment of FIG. 5A, the LED 500 is placed on a transparent plate 518, which resides on a lead frame 520. A metal mask is formed on the transparent plate 518, and one of the edges 530 of the metal mask 522 is electrically connected to the lead frame 520, while another edge 532 of the metal mask 522 is electrically connected to the p-GaN bonding pad 516. The LED 500 itself is attached to the transparent plate 518 through the p-type bonding pad 516 and metal mask 522. Wire bonding 524 is used to electrically connect the n-GaN bonding pad 514 with the lead frame 520. There are no intentional mirrors on the front 534 or back sides 536 of the LED 500. Instead, the lead frame 520 is designed to effectively extract light 538 from both sides of the LED, i.e., the back side 536, as well as the front side 534. Finally, an ohmic contact is placed below the bonding pad of the n-GaN 514 and p-GaN 516, but is not shown in the figure for simplicity.

FIG. 6A is a schematic illustrating a specific improved LED structure according the preferred embodiment of the present invention, wherein the improved LED structure 600 comprises an emitting layer 602, an n-type GaN layer 604, a p-type GaN layer 606, an ITO or ZnO layer 608, a transparent sub-mount 610, a surface 612 of the n-type GaN layer 604 that is roughened, textured, patterned or shaped, an n-GaN bonding pad 614 contacting the n-type GaN layer 604, and a p-GaN bonding pad 616 contacting the p-type GaN layer 606. The LED 600 resides on a transparent plate 618 that is placed on a metal lead frame 620. A metal mask 622 is formed on the transparent plate 618. A wire bond 624 is made from the bonding pad 614 to the metal lead frame 620, wherein the lead frame 620 includes both an anode 626 and a cathode 628. FIG. 6B is a plan view of the LED in FIG. 6A.

In the embodiment of FIG. 6A, the LED 600 is embedded in or combined with a molding 630 comprising a shaped optical element, such as an inverted cone shape, wherein the LED 600 and lead frame 620 are positioned within the inverted cone shape 630 such that light emitted from the top and/or bottom of the LED 600 is reflected by the sidewalls 632 of the inverted cone shape 630. Preferably, the sidewalls 632 of the molding 630 are mirrored, and the angle 634 of the sidewalls 632 of the inverted cone shape 630 reflects light 636 emitted from the top and/or bottom of the LED 600 to the front side 638 of the inverted cone shape 630.

For example, the molding 630 may be comprised of epoxy, which has a refractive index of n₂=1.5, whereas the refractive index of the air is n₁=1. As a result, the critical angle of the reflection is sin⁻¹ (1/1.5). Therefore, the angle 634 of the inverted cone shape 630 should be more than sin⁻¹ (1/1.5), which results in the light 636 being effectively extracted from the top surface or front side 638 of the inverted cone shape 630 due to the reflection from the sidewalls 632 of the inverted cone shape 630, or from a side 640 of the LED 600 itself. Alternatively or additionally, light may be emitted from a base, bottom surface or back side 642 of the inverted cone shape 630.

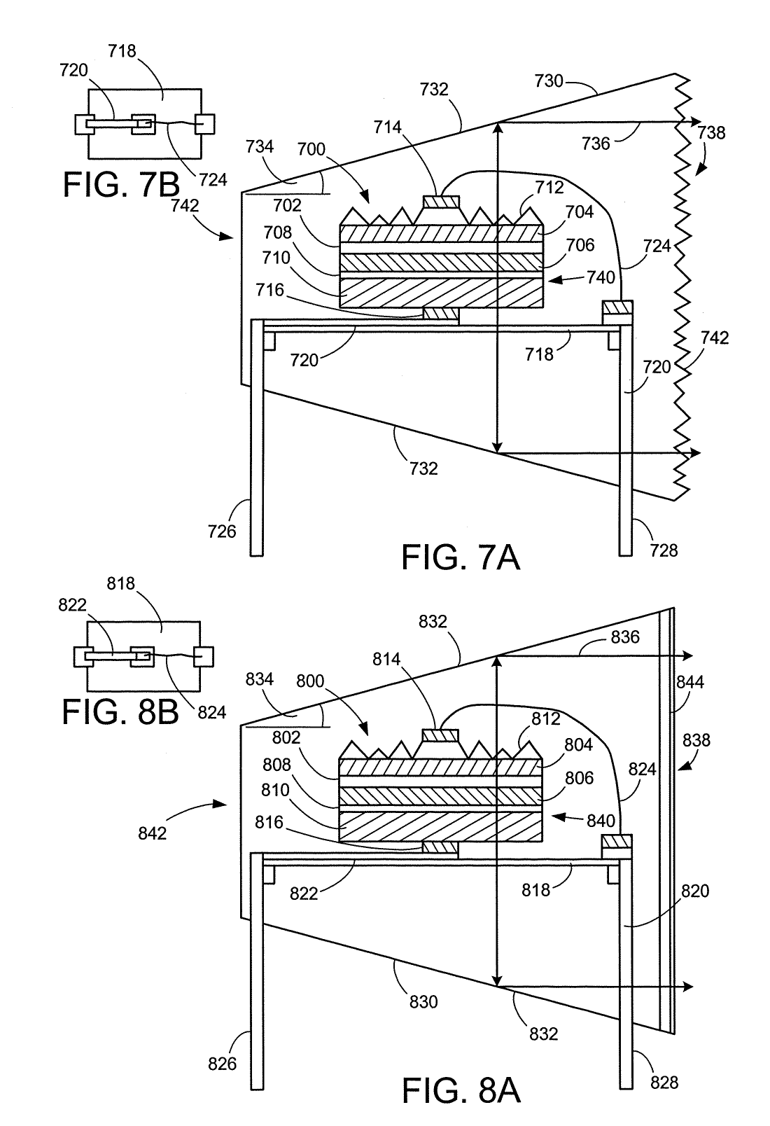

FIG. 7A is a schematic illustrating a specific improved LED structure according the preferred embodiment of the present invention, wherein the improved LED structure 700 comprises an emitting layer 702, an n-type GaN layer 704, a p-type GaN layer 706, an ITO or ZnO layer 708, a transparent sub-mount 710, a surface 712 of the n-type GaN layer 704 that is roughened, textured, patterned or shaped, an n-GaN bonding pad 714 contacting the n-type GaN layer 704 and a p-GaN bonding pad 716 contacting the p-type GaN layer 706. The LED 700 resides on a transparent plate 718, which is placed on a metal lead frame 720. A metal mask 722 is formed on the transparent plate 718, and a wire bond 724 is made from the n-GaN bonding pad 714 to the metal lead frame 720, wherein the lead frame 720 has both an anode 726 and a cathode 728. FIG. 7B is a plan view of the LED in FIG. 7A.

In the embodiment of FIG. 7A, the LED 700 is embedded in or combined with a molding 730 comprising a shaped optical element, such as an inverted cone shape, wherein the LED 700 and lead frame 720 are positioned within the inverted cone shape 730 such that light emitted from the top and/or bottom of the LED 700 is reflected by the sidewalls 732 of the inverted cone shape 730. Preferably, the sidewalls 732 of the molding 730 are mirrored, and the angle 734 of the sidewalls 732 of the inverted cone shape 730 reflects light 736 emitted from the top and/or bottom of the LED 700 to the front side 738 of the inverted cone shape 730.

For example, the molding 730 may be comprised of epoxy, which has a refractive index of n₂=1.5, whereas the refractive index of the air is n₁=1. As a result, the critical angle of the reflection is sin⁻¹ (1/1.5). Therefore, the angle 734 of the inverted cone shape 730 should be more than sin⁻¹ (1/1.5), which results in the light 736 being effectively extracted from the top surface or front side 738 of the inverted cone shape 730 due to the reflection from the sidewalls 732 of the inverted cone shape 730, or from a side 740 of the LED 600 itself. Alternatively or additionally, light may be emitted from a base, bottom surface or back side 742 of the inverted cone shape 730. Moreover, the top surface or front side 738 of the inverted cone shape 730 may be roughened, textured, patterned or shaped 742 to enhance light extraction.

FIG. 8A is a schematic illustrating a specific improved LED structure according the preferred embodiment of the present invention, wherein the improved LED structure 800 comprises an emitting layer 802, an n-type GaN layer 804, a p-type GaN layer 806, an ITO or ZnO layer 808, a transparent sub-mount 810, a surface 812 of the n-type GaN layer 804 that is roughened, textured, patterned or shaped, an n-GaN bonding pad 814 contacting the n-type GaN layer 804 and a p-GaN bonding pad 816 contacting the p-type GaN layer 806. The LED 800 resides on a transparent glass plate 818, which is placed on a metal lead frame 820. A metal mask 822 is formed on the transparent plate 818, and a wire bond 824 is made from the n-GaN bonding pad 814 to the metal lead frame 820, wherein the lead frame 820 has both an anode 826 and a cathode 828. FIG. 8B is a plan view of the LED in FIG. 8A.

In the embodiment of FIG. 8A, the LED 800 is embedded in or combined with a molding 830 comprising a shaped optical element, such as an inverted cone shape, wherein the LED 800 and lead frame 820 are positioned within the inverted cone shape 830 such that light emitted from the top and/or bottom of the LED 800 is reflected by the sidewalls 832 of the inverted cone shape 830. Preferably, the sidewalls 832 of the molding 830 are mirrored, and the angle 834 of the sidewalls 832 of the inverted cone shape 830 reflects light 836 emitted from the top and/or bottom of the LED 800 to the front side 838 of the inverted cone shape 830.

For example, the molding 830 may be comprised of epoxy, which has a refractive index of n₂=1.5, whereas the refractive index of the air is n₁=1. As a result, the critical angle of the reflection is sin⁻¹ (1/1.5). Therefore, the angle 834 of the inverted cone shape 830 should be more than sin⁻¹ (1/1.5), which results in the light 836 being effectively extracted from the top surface or front side 838 of the inverted cone shape 830 due to the reflection from the sidewalls 832 of the inverted cone shape 830, or directly from a side 840 of the LED 800 itself. Alternatively or additionally, light may be emitted from a base, bottom surface or back side 842 of the inverted cone shape 830. Moreover, the top surface or front side 838 of the inverted cone shape 830 may include one or more phosphor layers 844.

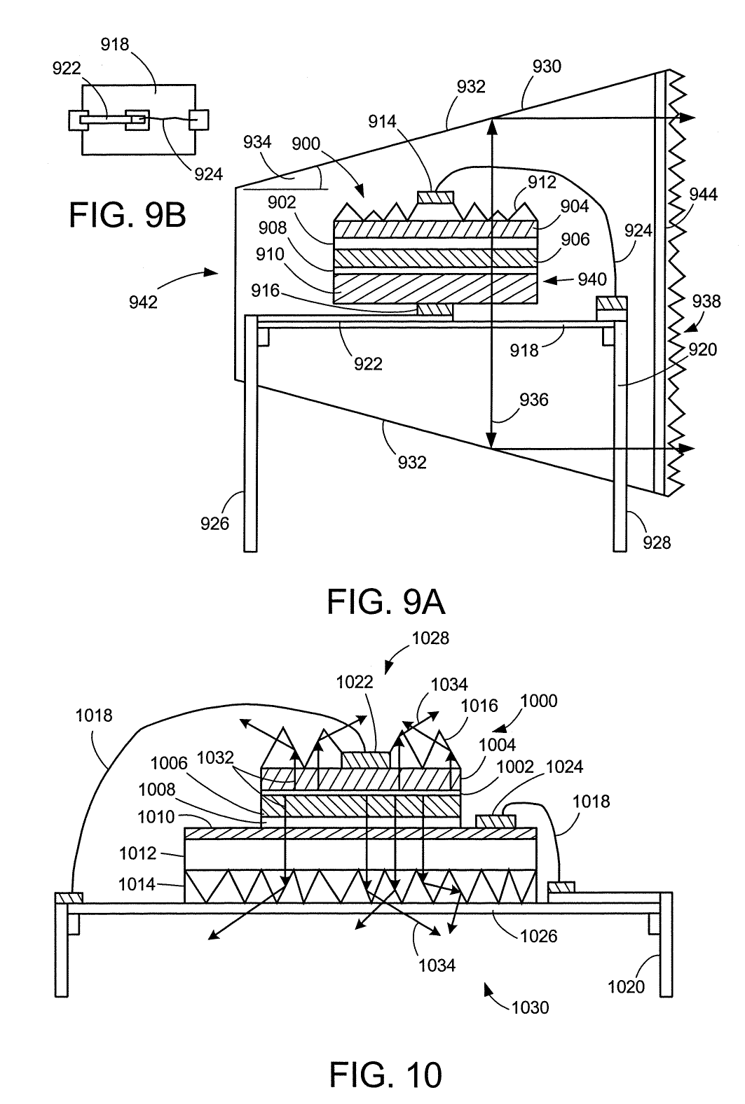

FIG. 9A is a schematic illustrating a specific improved LED structure according the preferred embodiment of the present invention, wherein the improved LED structure 900 comprises an emitting layer 902, an n-type GaN layer 904, a p-type GaN layer 906, an ITO or ZnO layer 908, a transparent sub-mount 910, a surface 912 of the n-type GaN layer 904 that is roughened, textured, patterned or shaped, an n-GaN bonding pad 914 contacting the n-type GaN layer 904 and a p-GaN bonding pad 916 contacting the p-type GaN layer 906. The LED 900 resides on a transparent plate 918, which is placed on a metal lead frame 920. A metal mask 922 is formed on the transparent plate 918, and a wire bond 924 is made from the n-GaN bonding pad 914 to the metal lead frame 920, wherein the lead frame 920 has both an anode 926 and a cathode 928. FIG. 9B is a plan view of the LED in FIG. 9A.

In the embodiment of FIG. 9A, the LED 900 is embedded in or combined with a molding 930 comprising a shaped optical element, such as an inverted cone shape, wherein the LED 900 and lead frame 920 are positioned within the inverted cone shape 930 such that light emitted from the top and/or bottom of the LED 900 is reflected by the sidewalls 932 of the inverted cone shape 930. Preferably, the sidewalls 932 of the molding 930 are mirrored, and the angle 934 of the sidewalls 932 of the inverted cone shape 930 reflects light 936 emitted from the top and/or bottom of the LED 900 to the front side 938 of the inverted cone shape 930.

For example, the molding 930 may be comprised of epoxy, which has a refractive index of n₂=1.5, whereas the refractive index of the air is n₁=1. As a result, the critical angle of the reflection is sin⁻¹ (1/1.5). Therefore, the angle 934 of the inverted cone shape 930 should be more than sin⁻¹ (1/1.5), which results in the light 936 being effectively extracted from the top surface or front side 938 of the inverted cone shape 930 due to the reflection from the sidewalls 932 of the inverted cone shape 930, or directly from a side 940 of the LED 900 itself. Alternatively or additionally, light may be emitted from a base, bottom surface or back side 942 of the inverted cone shape 930. Moreover, the top surface or front side 938 of the inverted cone shape 930 may include one or more phosphor layers 944, wherein the phosphor layers 944 may be roughened, textured, patterned or shaped to enhance light 936 extraction.

FIG. 10 is a schematic illustrating a specific improved LED structure according the preferred embodiment of the present invention, wherein the improved LED structure 1000 comprises an emitting layer 1002, an n-type GaN layer 1004, a p-type GaN layer 1006, an ITO layer 1008, a second ITO layer 1010, a glass layer 1012 and a transparent sub-mount 1014. The nitrogen face (N face) 1016 of the n-type GaN layer 1004 preferably is roughened, textured, patterned or shaped. The LED structure 1000 is attached and wire bonded 1018 to a lead frame 1020 via bonding pads 1022, 1024.

The LED 1000 resides on a transparent plate 1026, which is placed on the lead frame 1020. As noted above, wire bonding 1018 electrically connects the bonding pads 1022, 1024 to the lead frame 1020. An ohmic contact may be placed below the bonding pad 1022, but is not shown in the figure for simplicity.

Finally, there are no intentional mirrors at the front side 1028 or back side 1030 of the LED 1000, so emissions 1032 are not reflected. Instead, the lead frame 1020 is designed to effectively extract the light 1032 from both sides of the LED 1000, i.e., from the backside 1030 as well as the front side 1028 of the LED 1000. The roughened surfaces 1014 and 1016 increase transmission of extracted light 1034. Also, the efficiency of the LED 1000 is increased due to a lack of the re-absorption of the emissions 1032 within the LED 1000.

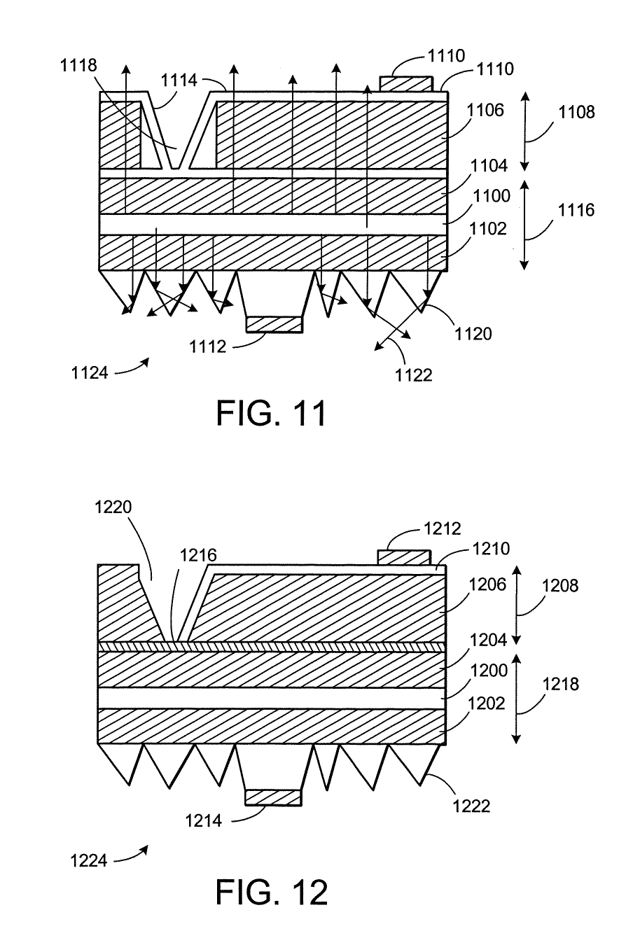

FIG. 11 is a schematic illustrating a specific improved LED structure according the preferred embodiment of the present invention, wherein the improved LED structure comprises an InGaN multi quantum well active layer 1100, an n-type GaN layer 1102, a p-type GaN layer 1104, an epoxy insulating layer 1106 (approximately 400 microns thick 1108), a bonding pad 1110, an ohmic electrode/bonding pad 1112, and an ITO or ZnO layer 1114. The thickness 1116 of the combined n-type GaN layer 1102, active layer 1100 and p-type GaN layer 1104 is approximately 5 microns.

FIG. 12 is a schematic illustrating a specific improved LED structure according the preferred embodiment of the present invention, wherein the improved LED structure comprises an InGaN active layer 1200 having MQWs, an n-type GaN layer 1202, a p-type GaN layer 1204, an epoxy insulating layer 1206 (approximately 400 microns thick 1208), a narrow stripe Au connection layer 1210, a bonding pad 1212, an ohmic electrode/bonding pad 1214, and an ITO or ZnO layer 1216. The thickness 1218 of the combined n-type GaN layer 1202, active layer 1200 and p-type GaN layer 1204 is approximately 5 microns.

In both FIGS. 11 and 12, a thick epoxy layer 1106, 1206 is used, rather than the glass 1012 shown in FIG. 10. To make electrical contact, the epoxy insulating layers 1106, 1206 are partially removed, and the ITO layer 1114, which is a transparent metal oxide, or a narrow stripe of Au or other metal layer 1216, are deposited on the epoxy layers 1106, 1206, as well as within a hole or depression 1118, 1220 in the surface of the epoxy layers 1106, 1206 to make electrical contact with the p-GaN layer 1104, 1206.

In addition, both FIGS. 11 and 12 show that roughened, textured, patterned or shaped surfaces 1120, 1222 are formed on the nitrogen face (N-face) of the n-type GaN layers 1102, 1202. These roughened, textured, patterned or shaped surfaces 1120, 1222 enhance the extraction of light.

Note that, if a GaN substrate is used instead of a sapphire substrate, laser de-bonding would not be required and, as a result, the sub-mounts 1106, 1206 would not be required. Moreover, if the LED structure is created on a GaN substrate, the ITO layers 1114, 1216 would be deposited on the p-type GaN 1104, 1204 and the backside of the GaN substrate 1124, 1224, which is an N-face GaN, could be etched using a wet etching, such as KOH and HCL, in order to form the surfaces 1120, 1222 that are roughened, textured, patterned or shaped on the N-face GaN 1102, 1202.

Note also that, if the surfaces of the ITO layers 1114, 1216 are roughened, textured, patterned or shaped, light extraction is increased through the ITO layers 1114, 1216. Even without the ITO layers 1114, 1216 on the p-type GaN layers 1104, 1204, the roughening, texturing, patterning or shaping of the surfaces of the p-type GaN layers 1104, 1204 (i.e., the surface opposite the emitting layers 1100, 1200) is effective to increase the light extraction through the p-type GaN layers 1104, 1204.

Finally, ohmic contacts for the n-type GaN layers 1102, 1202, and the ITO or ZnO layers 1114, 1206, may be created after the surface roughening, texturing, patterning or shaping of the n-type GaN layers 1102, 1202. Because ITO and ZnO have a similar refractive index as GaN, the light reflection at the interface between ITO, ZnO and GaN is minimized.

Thereafter, bonding pads are formed on n-type GaN layers 1102, 1202 and p-type GaN layers 1104, 1204, respectively. In this case, the GaN substrate side 1124,1224 is placed on the transparent plate with a metal mask using metal bonding. The p-GaN bonding pads 1110, 1212 are wire bonded on the lead frame directly. Moreover, the LED may be embedded within a molding, in a manner similar to those shown in FIGS. 6-9.

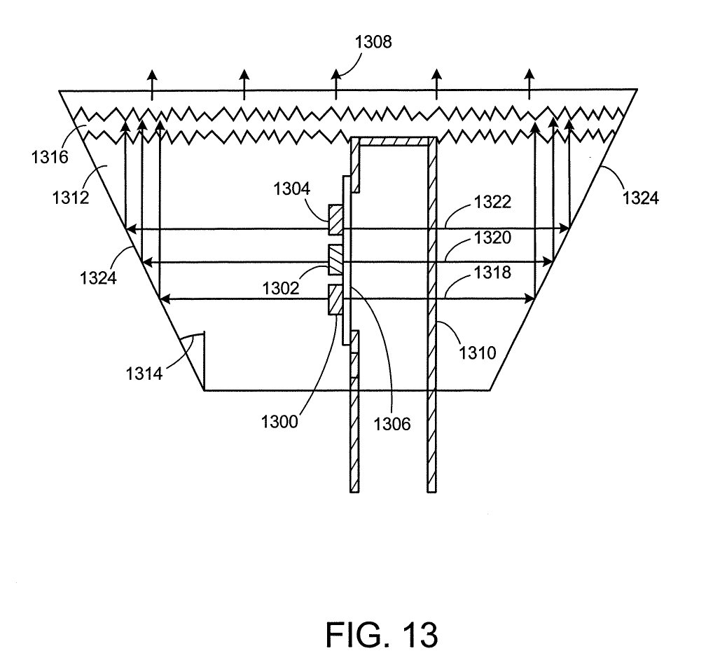

FIG. 13 is a schematic illustrating a specific improved LED structure according the preferred embodiment of the present invention, wherein the improved LED structure comprises blue 1300, green 1302 and red 1304 LEDs (or LED emitting layers) that are placed on a transparent plate 1306, in order to make white LED light 1308 from the three primary color LEDs 1300, 1302 and 1304, without using a phosphor. The transparent plate 1306 (e.g. glass) is placed on a metal lead frame 1310, and each LED 1300, 1302, 1304 is electrically connected to a metal mask on the transparent plate 1306 by wire bonding (not shown).

Preferably, the LEDs 1300, 1302, 1304 are embedded in a mold or shaped optical element 1312, such as an inverted cone made of epoxy or glass, which has an angle 1314 optimized for light extraction. In addition, the inverted cone 1312 contains a light mixing layer 1316 to mix each color uniformly. The blue 1318, green 1320 and red 1322 light emitted by the LEDs 1300, 1302 and 1304 is reflected by the surfaces 1324 towards the light mixing layer 1316, wherein the light mixing layer 1316 mixes the blue 1318, green 1320 and red 1322 light to create white light 1308 that is extracted from the inverted cone 1312. Moreover, the light mixing layer 1316 works as a light diffusion layer that outputs uniform light from the inverted cone shape 1312.

### ADVANTAGES AND IMPROVEMENTS

One advantage of the present invention is that all of the layers of the LED are transparent for the emission wavelength, except for the emitting layer, such that the light is extracted effectively through all of the layers.

Moreover, by avoiding the use of intentional mirrors with the LED, re-absorption of light by the LED is minimized, light extraction efficiency is increased, and light output power is increased.

The combination of a transparent electrode with roughened, textured, patterned or shaped surfaces, with the LED embedded within a shaped optical element or lens, results in increased light extraction.

### REFERENCES

The following references are incorporated by reference herein:
1. Appl. Phys. Lett., 56, pp. 838-39 (1990).
2. Appl. Phys. Lett., 64, pp. 2839-41 (1994).
3. Appl. Phys. Lett., 81, pp. 3152-54 (2002).
4. Jpn. J. Appl. Phys., 43, L1285-88 (2004).
5. Jpn. J. Appl. Phys., 45, L1084-L1086 (2006).
6. Jpn. J. Appl. Phys., 34, L797-99 (1995)
7. Jpn. J. Appl. Phys., 43, L180-82 (2004).
8. Fujii T., Gao Y., Sharma R., Hu E. L., DenBaars S. P., Nakamura S., “Increase in the extraction efficiency of GaN-based light-emitting diodes via surface roughening,” Appl. Phys. Lett., 84, pp. 855-858 (2004).

### CONCLUSION

This concludes the description of the preferred embodiment of the present invention. The foregoing description of one or more embodiments of the invention has been presented for the purposes of illustration and description. It is not intended to be exhaustive or to limit the invention to the precise form disclosed. Many modifications and variations are possible in light of the above teaching.

What is claimed is:

1. A light emitting device, comprising:
a plurality of III-nitride layers, including an active region that emits light, wherein all of the layers except for the active region are transparent for an emission wavelength of the light, such that the light is extracted effectively through all of the layers; and
a lead frame for supporting the III-nitride layers, wherein the III-nitride layers reside on a transparent plate in the lead frame, and the light emitted from the III-nitride layers is transmitted through the transparent plate in the lead frame.

2. The device of claim 1, wherein one or more transparent conducting layers are positioned to electrically connect the III-nitride layers.

3. The device of claim 1, wherein one or more current spreading layers are deposited on the III-nitride layers, and the transparent conducting layers are deposited on the current spreading layers.

4. The device of claim 1, wherein mirrors or mirrored surfaces are eliminated from the layers to minimize internal reflections in order to minimize re-absorption of the light by the active region.

5. The device of claim 1, wherein a surface of one or more of the III-nitride layers is roughened, textured, patterned or shaped to enhance extraction of the light.

6. The device of claim 1, wherein the III-nitride layers reside on a transparent conductive substrate or sub-mount.

7. The device of claim 1, wherein a metal mask is formed on the transparent plate for electrically connecting the III-nitride layers to the lead frame.

8. The device of claim 1, wherein the III-nitride layers are embedded in or combined with a shaped optical element, and the light is extracted from one or more surfaces of the III-nitride layers before entering the shaped optical element and subsequently being extracted.

9. The device of claim 8, wherein at least a portion of the light entering the shaped optical element lies within a critical angle and is extracted.

10. The device of claim 8, wherein one or more surfaces of the shaped optical element is roughened, textured, patterned or shaped to enhance extraction of the light.

11. The device of claim 8, wherein the shaped optical element includes a phosphor layer.

12. The device of claim 8, wherein the shaped optical element is an inverted cone shape.

13. The device of claim 12, wherein the III-nitride layers are positioned within the inverted cone shape such that the light is reflected by sidewalls of the inverted cone shape.

14. The device of claim 12, wherein an insulating layer covering the III-nitride layers is partially removed, and a conductive layer is deposited within a hole or depression in the surface of the insulating layer to make electrical contact with the III-nitride layers.

15. The device of claim 1, wherein the plurality of III-nitride layers comprise a plurality of light emitting diodes that emit at different wavelengths.

16. The device of claim 15, wherein a light mixing layer mixes the light at different wavelengths emitted by the light emitting diodes.

17. A method of fabricating a light emitting device, comprising:
forming a plurality of III-nitride layers, including an active region that emits light, wherein all of the layers except for the active region are transparent for an emission wavelength of the light, such that the light is extracted effectively through all of the layers; and
supporting the III-nitride layers on a lead frame, wherein the III-nitride layers reside on a transparent plate in the lead frame, and the light emitted from the III-nitride layers is transmitted through the transparent plate in the lead frame.
